(19) United States
(12) Patent Application Publication
(10) Pub. No.: US 2023/0208310 A1
(43) Pub. Date: Jun. 29, 2023

(54) ELECTRICAL GENERATOR SYSTEM

(71) Applicant: Rolls-Royce Deutschland Ltd & Co KG, Blankenfelde-Mahlow (DE)

(72) Inventors: Ferenc ANTAL, Budapest (HU); Tamás Attila FODOR, Sárospatak (HU); András Zsigmond LÉGÁR, Budapest (HU); Tibor SÜLE, Budapest (HU)

(21) Appl. No.: 18/080,307

(22) Filed: Dec. 13, 2022

(30) Foreign Application Priority Data
Dec. 23, 2021 (EP) 21217596.2

(51) Int. Cl. H02M 7/00; H05K 7/14

(52) U.S. Cl. CPC H02M 7/003; H05K 7/14329

(57) ABSTRACT

An electrical generator system includes a generator unit and an inverter unit. The generator unit is coupled to the inverter unit through a coupling mechanism, wherein the coupling mechanism includes at least one busbar connection.

The present patent document claims the benefit of European Patent Application No. 21217596.2, filed Dec. 23, 2021, which is hereby incorporated by reference in its entirety.

### TECHNICAL FIELD

The disclosure relates to an electrical generator system having a generator unit coupled to an inverter unit via a coupling mechanism.

### BACKGROUND

Electrical generators are used in many applications, increasingly also in propulsion systems for aircraft. Alternating current (AC) generators used in this context may require a coupling with an inverter. An inverter is a device changing a direct current (DC) current into an AC current required in this case by the generator.

For this purpose, it is known that generators and inverters as separate units are coupled by cables. As several cables are required for the electrical connection, the weight of the overall generator system is increased.

In particular, in aircraft or aerospace applications, lightweight and compact solutions are required.

### SUMMARY

The scope of the present disclosure is defined solely by the appended claims and is not affected to any degree by the statements within this summary. The present embodiments may obviate one or more of the drawbacks or limitations in the related art.

The electrical generator system disclosed herein includes a generator unit and an inverter unit, wherein the generator unit coupled to the inverter unit through a coupling mechanism or device. The coupling mechanism includes at least one busbar connection. This advantageously provides a cable-free electrical connection between the generator unit and the inverter unit.

A busbar may be a metallic contact (e.g., plug, bar, strip, etc.). The busbar may be uninsulated and may have sufficient mechanical stiffness, unlike a cable.

In one embodiment, the generator unit includes at least one a male part of the busbar connection and the inverter unit includes at least one female part of the busbar connection.

For sufficient mechanical stiffness, the male part of the busbar connection may have a length to diameter ratio in a range of 7:1 to 3:1.

In another embodiment, a busbar insulator element is configured to electrically insulate the busbar connection, (e.g., the female part of the busbar connection), against other elements of the generator system. The busbar insulator element may include a tubular section for an electrical insulation in radial direction and/or a disc element, in particular attached to the tubular section for an electrical insulation in axial direction. Such a design may achieve insulation effect in more than one direction. For an effective axial insulation, the disc element of the busbar insulator element has an outer diameter being 1.2 to 2 times the inner diameter of the tubular section.

As the electrical generator system emits heat, the busbar connection, (e.g., the male part and/or the female part of the busbar connection), may be thermally coupled to a cooling device, (e.g., a heat sink and/or an active cooling medium). The heat sink may be a passive cooling medium such as an inverter unit part with a suitably high heat capacity.

In another embodiment, the female part of the busbar connection and/or the male part of the busbar connection are electrically coupled to a transducer for measuring the current and/or the voltage at the busbar connection. The current data may be used in the control of the generator system.

The busbar connection may include a receiving element with the female part of the busbar connection. In particular, the terminal electrical contacts of the receiving element may be offset from each other. This provides some design flexibility to have the electrical terminals at very different locations while still being connected through the busbar connection with the receiving element.

In a further embodiment, the female part of the busbar connection includes a tubular part and at least one connection element for establishing an electric connection with the inverter unit and/or the generator unit. The receiving element allows for a geometric flexibility to geometrically decouple the tubular female part (and the matching plug shaped male part) and the connection to other parts in the generator unit and/or the inverter unit. For example, the at least one connection element is positioned above or below a plane of the axis of the tubular female part of the busbar connection. For good electrical conductivity, the receiving element includes copper or is made from copper. On the outside, the receiving element may include some insulation material, in particular, a foil material.

In another embodiment, at least one part of the system, (e.g., the heat sink and/or the busbar connection with the receiving element), is axially adjustable with an adjustment mechanism or device relative to a fixed part in the generator unit and/or inverter unit, (e.g., the generator unit housing and/or the inverter unit housing). This axial adjustability may prevent an overconstraining of the assembly.

### BRIEF DESCRIPTION OF THE DRAWINGS

Embodiments of the disclosure are shown in the figures, wherein:

FIG. 1 shows a perspective view of an embodiment of an electrical generator system with a generator and an inverter as separate units;

FIG. 2 shows a sectional view of a detail of the generator unit and the inverter unit of FIG. 1 connected by a busbar connection;

FIG. 3A shows a perspective rear view of an embodiment of a busbar insulator element;

FIG. 3B shows a perspective frontal view of the busbar insulator element of FIG. 3A;

FIG. 4 shows a perspective view of an embodiment of the busbar connection in the inverter unit;

FIG. 5 shows a perspective view of the busbar connection of FIG. 4 with a clamping element removed;

FIG. 6 shows a perspective view of the busbar connection of FIG. 5 with a busbar insulator element removed;

FIG. 7 shows a perspective view of the busbar connection of FIG. 6 with a current transducer removed, showing a receiving element of the busbar connection;

FIG. 8 shows a perspective view of an embodiment of a clamping element;

FIG. 9. Shows a perspective view of an embodiment of a fixing nut;

FIG. 10 shows a perspective view of an embodiment of the receiving element;

FIG. 11A shows a perspective sectional view of an embodiment of the transducer coupled to the busbar connection;

FIG. 11B shows a frontal view of an embodiment of the inverter unit with a plurality of transducers;

FIG. 12 a shows perspective overview of an embodiment of the inverter unit;

FIG. 13 shows a sectional view through a detail of the inverter unit showing an axial adjustment mechanism or device, according to an embodiment.

### DETAILED DESCRIPTION

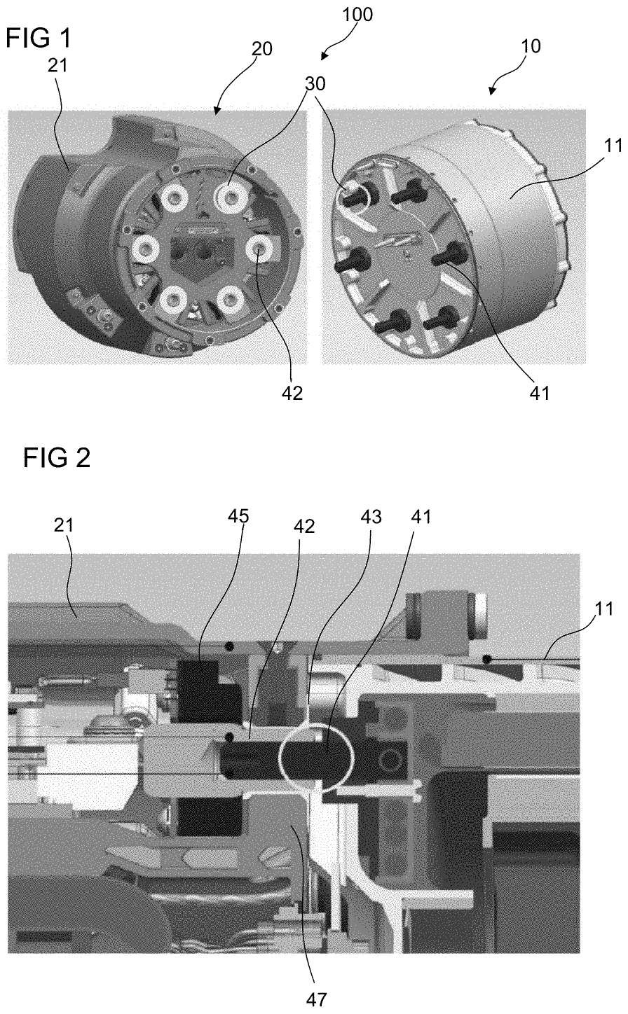

In the following FIGS. 1 to 13, details of an exemplary embodiment of an AC generator system 100 including a generator unit 10 and an inverter unit 20 are described. The relevant elements visible in the figures are described in their technical context, not every figure.

FIG. 1 shows an electrical generator unit 10 on the right and an inverter unit 20 on the left in a non-connected situation. The generator unit 10 and the inverter unit 20 include respective housings 11, 21.

In an assembled, electrically connected situation (in part, e.g., shown in FIG. 2), it is the aim to provide the electrical generator system 100 that is lightweight and compactly connected so that the system may be used in an aerospace or aircraft context.

The generator unit 10 is coupled to the inverter unit 20 through a coupling mechanism or device 30, wherein the coupling mechanism 30 includes at least one busbar connection 41, 42.

As depicted in FIG. 1 and in more detail in the following figures, the generator unit 10 may include a plurality (e.g., six) of male parts 41 of the busbar connection. The inverter unit 20 includes the matching plurality of female parts 42 of the busbar connection.

In other embodiments, the generator unit 10 includes the female parts and the inverter unit 20 the male parts. Also, mixed arrangement of male parts 41 and female parts 42 are possible.

The busbar connection with the male and female parts 41, 42 enables a direct, non-cable connection between the generator unit 10 and the inverter unit 20, saving volume and weight.

The male part 41 is dimensioned as a cylindrical plug with a circular cross-section. The ratio of the length to diameter is about 5:1. The plug-shaped male part 41 of the busbar connection (and the corresponding female part 42) defines an axial direction A, which is referred to in the following description.

In other embodiments, the length-diameter ratio of the male part 41 may be in a range of 7:1 and 3:1, therein providing a stable, robust electrical connection. In further embodiments, the male part 41 may have a different shape, e.g., a rectangular, plate-like shape, or a tubular shape. The cross-section may also be non-circular, e.g., polygonal or elliptic. The female part 42 of the busbar connection is complementary shaped to the male part 41.

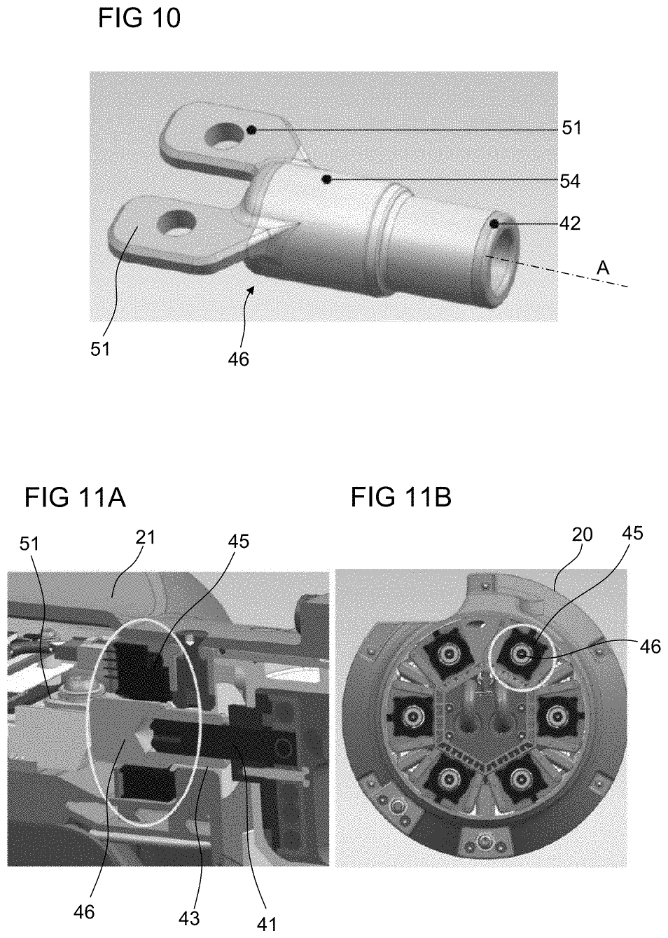

The female part 42 of the busbar connection is shown in more detail in FIG. 10.

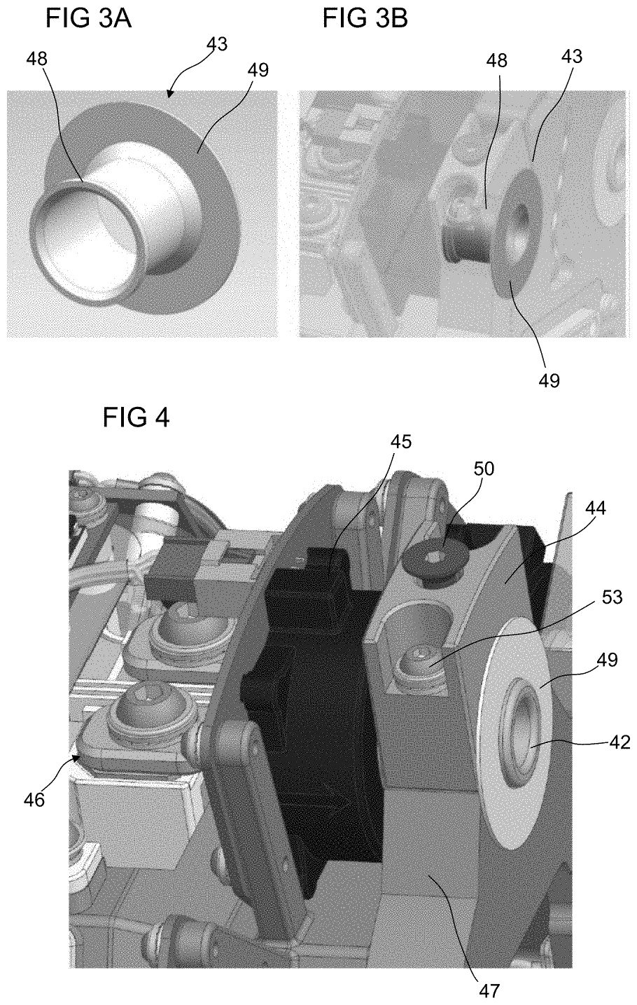

As the electrical current flows through the male and female parts 41, 42, some electrical insulation against other parts is introduced circumferentially on the outside of the female part 42 in the form of a busbar insulator element 43, shown in more detail in FIG. 3A and 3B.

The busbar insulator element 43 may include a tubular section 48 (seen in the front of FIG. 3A) which on one end includes a disc element 49. The tubular section 48 electrically insulates the female part 42 radially, the disc element 49 axially against other parts of the inverter unit, as depicted in FIG. 2. The outer diameter of the disc element 49 may be in a range of 1.2 to 2 times the inner diameter of the tubular section 48. The busbar insulator element 43 may be made from resin and may be produced through a 3D printing process.

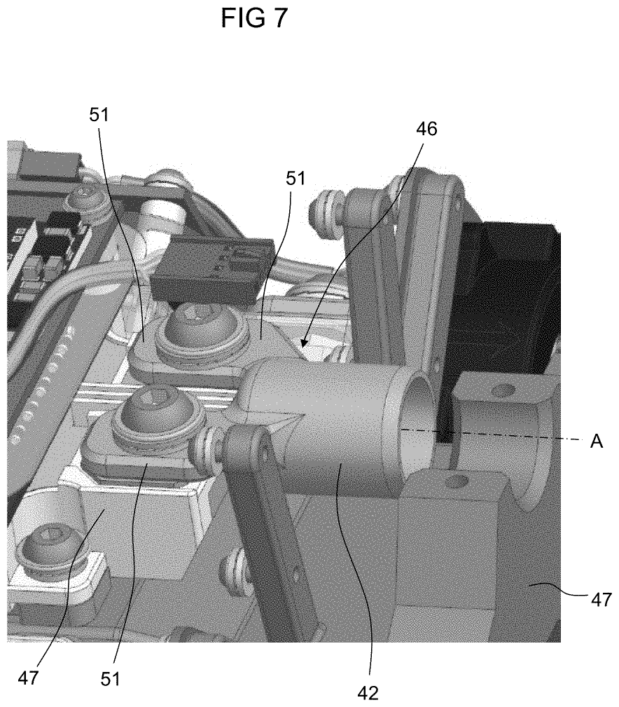

As indicated above, the axial direction A defines the axis along the male part 4 of the busbar connection is inserted into the female part 42. The axis A extends along a tubular part of the female part 42 of the busbar connection (see, e.g., FIG. 7).

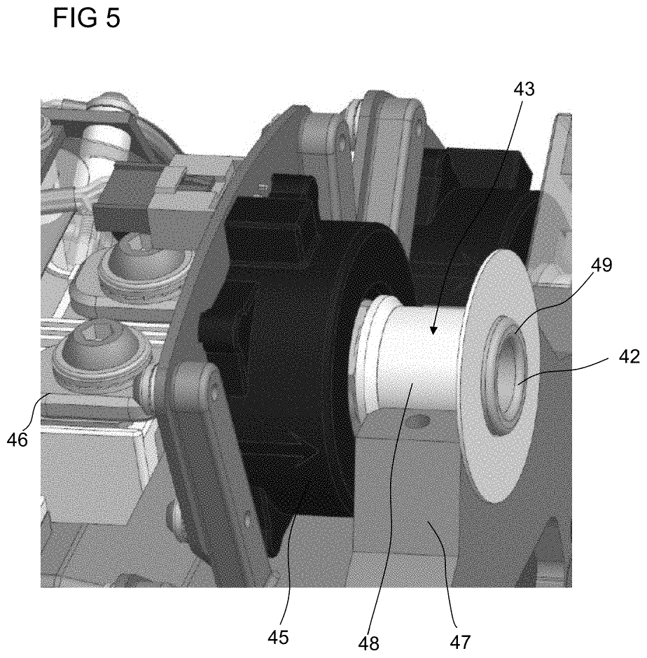

In the assembly shown in FIG. 2, the busbar insulator element 43 prevents current from leaking, e.g., into a heat sink 47 and into a clamping element 44 (shown in detail, e.g., in FIG. 4). The heat sink 47 provides some cooling capability to the busbar connection. The heat sink 47 may be part of the inverter unit 20 and may be manufactured by a 3D printing process.

The heat sink 47, (e.g., as a passive and/or active device), is just one of the possible cooling devices to cool the busbar connection. An active cooling device might use a cooling fluid thermally coupled to the busbar connection.

The busbar connection with the male part 41 and the female part 42 should remain in place relative to other parts of the inverter unit 20 for providing a safe electrical connection between the generator unit 10 and the inverter unit 20. But it is also an issue to keep the busbar connection free (as far as technically possible) from dynamic stresses, e.g., mechanical stresses. Furthermore, the busbar connection should have a good heat exchange with the cooling device, here the heat sink 47. Therefore, a tight screw connection with fastening screes 53 (see, e.g., FIG. 4) in the embodiment shown presses the heat sink 47 against the busbar connection, therein providing low thermal resistance.

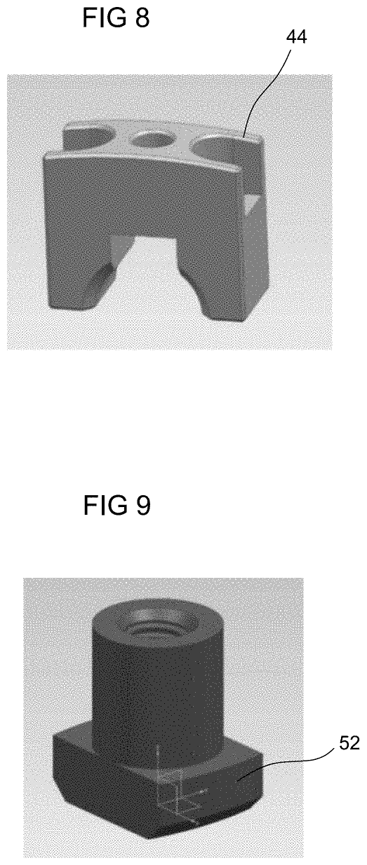

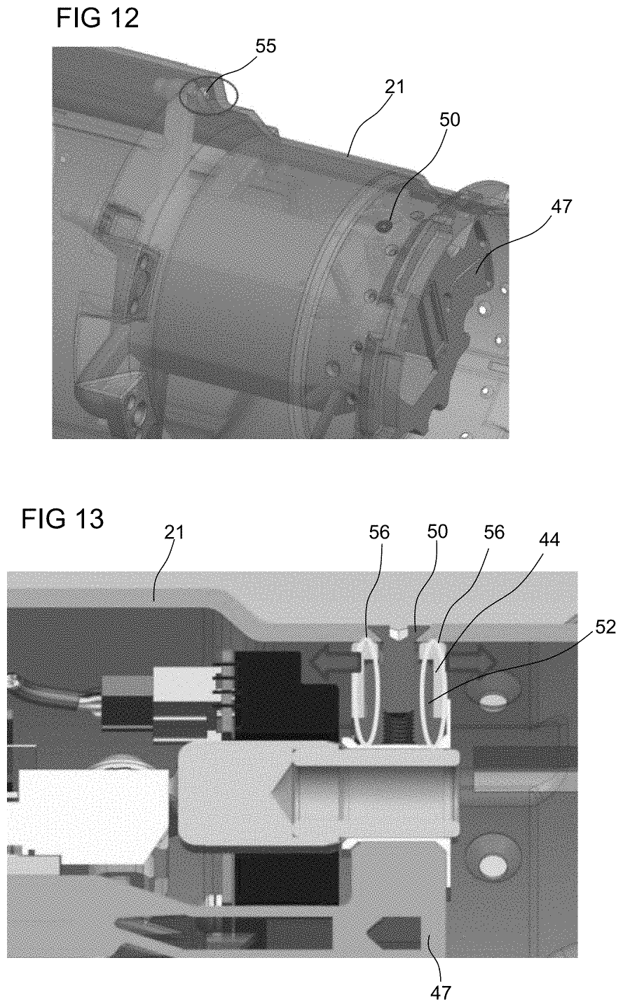

In FIG. 4, a fastener 50 (e.g., a screw) for adjusting the axial position within the clamping element 44 is shown in a partly unscrewed position. Details of the axial adjusting are described in connection with FIGS. 12 and 13. The clamping element 44 itself is shown in more detail in FIG. 8.

The clamping element 44 fixes the busbar insulator element 43 against a rigid part of the inverter unit 10 by using the fastening screws 53. Thereby, it suppresses vibrations in the busbar connection. The clamping also improved the heat transfer from the busbar connection to the heat sink 47.

In FIG. 4, only the disc element 49 of the bus bar insulator element 43 is depicted. In this example, the busbar insulator element 43 surrounds the female part 42 of the busbar connection. An electrical transducer 45 is positioned axially behind the clamping element 44 for measuring the current flowing through the busbar connection. The term “behind” in this context is defined relative to the opening of the female part 42 of the busbar connection which is defined as the “front.”

The electrical transducer 45 is connected through a board with the body of the inverter unit 20. Further details are shown in FIG. 11A and 11B.

A cross-section of the electrical transducer 45 is shown in FIG. 2, showing the electrical connection with the axial rear part of the female part 42 of the busbar connection.

In FIGS. 5 to 7, the busbar connection of the embodiment discussed herein is shown in different views. In these examples, some parts of the busbar connection are removed to show part hidden from view in other figures.

FIG. 5 shows a similar view as in FIG. 4, but with the clamping element 44 removed. This allows a more complete view of the busbar insulator element 43.

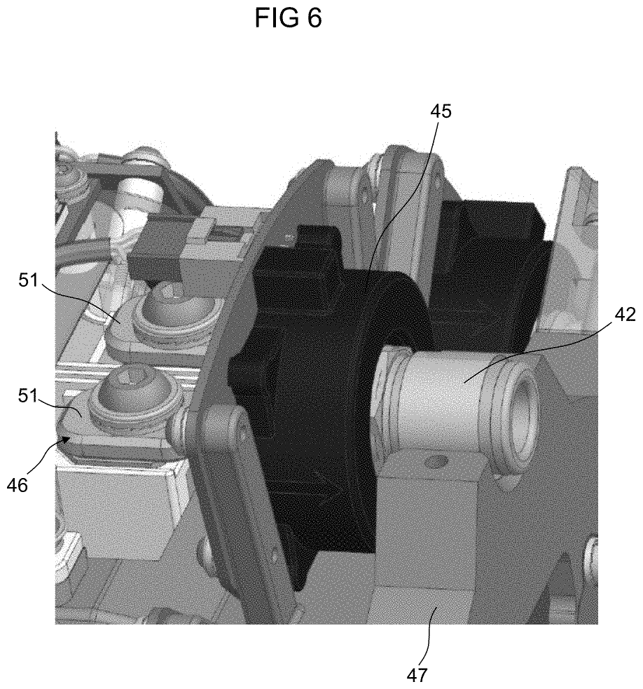

FIG. 6 shows a similar view as in FIG. 5, but with the busbar insulator element 43 removed. This shows the tubular part of the female part 42 of the busbar connection.

FIG. 7 shows a similar view as in FIG. 6, but with the transducer 45 and its board removed.

The female part 42 of the busbar connection is part of a receiving element 46 which includes two connection elements 51. As depicted in more detail in FIG. 10, the two connection elements 51 are positioned laterally at the opposite end to the opening of the female part 42. Furthermore, the connection elements 51 are positioned above the axis A. The connection elements 51 in the embodiment shown are two plates which are mounted above the plane with the axis A. This allows that the receiving element 46 may be fastened to the inverter unit 20 in a volume-economic way. Both plates of the connection elements 51 include holes for the screw connection shown e.g. in FIG. 7. The current flowing through the busbar connection flows through the tubular female part 42 and through the plates 51. The material underneath of the connection element 51 may also be configured to be a heat sink 47 to keep this part of the busbar connection cool.

In other embodiments, only one connection element 51 or more than two connection elements 51 (not necessarily shaped as a plate) may be used to establish the electrical connection through the busbar connection.

In FIG. 8, the clamping element 44 is shown without the inverter unit 20 and other parts. In this example, the clamping element is shaped as an arch. On the top side, two fastening screws 53 may be inserted on the right and left hand side (see, e.g., FIG. 4). In the middle between those fastening screws 53, the radial fastener 50 (see, e.g., FIG. 4) may be used to axially adjust the assembly as will be described below in connection with FIGS. 12 and 13.

FIG. 9 shows a fixing nut 52 as the counterpart of the radial fastener 50 (also seen e.g. in FIG. 4), which is used for the adjustment.

FIG. 10 shows the receiving element 46 with the tubular female part 42 of the busbar connection on the right hand side, (i.e., the frontal side). On the left hand side, (i.e., the rear), the two connection elements 51 are depicted, each connection element having a bore for taking up screws of fastening the receiving element 46 to a part in the inverter unit 20. By attaching the connection elements 51 in a plane higher than the plane of the axis A, (e.g., radially off center), the receiving element 46 may be fitted into the inverter unit 20 with a very small volume. There is a radial offset between the female part 46 as a first terminal electrical contact and the connection elements 51 as a second terminal electrical contact.

This shows that the receiving element 46 may have a more complex busbar form to transport the current within the inverter unit 20. This means that the female part 42 of the busbar connection and the other parts of the inverter unit 20 may be configured independently from each other. The busbar connection with the receiving element 46 may bridge, e.g., radial distances if that helps to keep the overall volume small.

The receiving element 46, or at least parts of it, are made from copper 1000, which may be produced by milling. Alternatively, the receiving element 46 may be manufactured by a casting process. The surface of the receiving element 46 is at least partially coated with nickel. To electrically insulate the receiving element 46 against other parts of the inverter unit 20, the receiving element 46 includes insulation material 54, such as, e.g., Kapton foil.

In FIGS. 11A and 11B, more details of the transducer 45 are shown. Axially behind the busbar insulator element 43, the current transducer 45 surrounds the receiving element 46 concentrically. FIG. 11B shows the inverter unit 20 in an axial view with six transducers 45 surrounding the six receiving elements 46.

In FIGS. 12 and 13, some mechanisms or devices for axially adjusting the busbar connection axially relative to other parts in the inverter unit 20 are described. This prevents overconstraining the structure.

In FIG. 12, the 3D printed heat sink 47 is shown to be fastened with screws 55 (only one shown) to the inverter housing 21, in several locations. All of these screws are in axial screw connections. As the clamping element 44 is fixed against the heat sink 47 as well (see FIG. 4), some axial flexibility is required to prevent an overconstraining.

To that effect, within the clamping element 44, axial gaps 56 (encircled in FIG. 13) are provided. This allows an axial adjustment (see arrows in FIG. 13) of the inverter housing 21 relative to the heat sink 47 (and the receiving element 46). The radial screw 50 (see, e.g., FIG. 2, 4, or 12) is threaded with the fixing nut 52 (see also, e.g., FIG. 2). By tightening the radial fastener screw 50, the axial position may be fixed. This determines the relative axial position of the housing 21 to the heat sink 47.

The axial adjustment enables an easier assembly as tolerances may be overcome. Additionally, the axial adjustment may help in adjusting for thermal expansions.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

### LIST OF REFERENCE NUMBERS

10 generator unit
11 generator housing
20 inverter unit
21 inverter housing
30 coupling mechanism
41 male part of busbar connection
42 female part of busbar connection
43 busbar insulator element
44 clamping element
45 current transducer
46 receiving element of busbar connection
47 heat sink
48 tubular section
49 disc element
50 radial fastener
51 connection element of receiving element
52 fixing nut for the fastener
53 fastening screws
54 insulation material of receiving element
55 screw connecting heat sink with inverter housing
56 axial gap in clamping element
100 generator system
A axis of male/female part of the busbar connection

1. An electrical generator system comprising:
a generator unit; and
an inverter unit,
wherein the generator unit is coupled to the inverter unit through a coupling mechanism, and
wherein the coupling mechanism comprises a busbar connection.

2. The electrical generator system of claim 1, wherein the generator unit comprises a male part of the busbar connection, and
wherein the inverter unit comprises a female part of the busbar connection.

3. The electrical generator system of claim 2, wherein the male part of the busbar connection has a length to diameter ratio in a range of 7:1 to 3:1.

4. The electrical generator system of claim 1, wherein a busbar insulator element is configured to electrically insulate at least one component of the busbar connection against other elements of the electrical generator system.

5. The electrical generator system of claim 4, wherein the at least one component of the busbar connection is a female part of the busbar connection.

6. The electrical generator system of claim 4, wherein the busbar insulator element comprises a tubular section for an electrical insulation in a radial direction and/or a disc element.

7. The electrical generator system of claim 6, wherein the disc element of the busbar insulator element is attached to the tubular section of the busbar insulator element for an electrical insulation in an axial direction.

8. The electrical generator system of claim 7, wherein the disc element of the busbar insulator element has an outer diameter being 1.2 to 2 times an inner diameter of the tubular section.

9. The electrical generator system of claim 1, wherein a male part and/or a female part of the busbar connection is thermally coupled to a cooling device.

10. The electrical generator system of claim 9, wherein the cooling device is a heat sink, an active cooling medium, or a combination thereof.

11. The electrical generator system of claim 1, wherein a female part and/or a male part of the busbar connection is electrically coupled to a transducer for measuring a current and/or a voltage at the busbar connection.

12. The electrical generator system of claim 1, wherein the busbar connection comprises a receiving element, and
wherein the receiving element comprises a female part of the busbar connection.

13. The electrical generator system of claim 12, wherein terminal electrical contacts of the receiving element are radially offset from each other.

14. The electrical generator system of claim 12, wherein the female part of the busbar connection comprises a tubular part and at least one connection element for establishing an electric connection with the inverter unit and/or the generator unit.

15. The electrical generator system of claim 14, wherein the at least one connection element is positioned above or below a plane of an axis of the tubular part of the female part of the busbar connection.

16. The electrical generator system of claim 12, wherein the receiving element comprises copper.

17. The electrical generator system of claim 12, wherein the receiving element comprises an insulation material.

18. The electrical generator system of claim 17, wherein the insulation material is a foil material.

19. The electrical generator system of claim 1, wherein at least one part of a heat sink and/or the busbar connection with a receiving element is axially adjustable with an adjustment mechanism relative to a fixed part in the generator unit and/or the inverter unit.

20. The electrical generator system of claim 19, wherein the fixed part in the generator unit and/or the inverter unit is a generator unit housing and/or an inverter unit housing.
